(19) United States
(12) Patent Application Publication
(10) Pub. No.: US 2008/0084731 A1
(43) Pub. Date: Apr. 10, 2008

(54) DRAM devices including fin transistors and methods of operating the DRAM devices

(75) Inventors: Chul Lee, Seoul (KR); Dong-Gun Park, Seongnam-si (KR); Woun-Suck Yang, Suwon-si (KR); Makoto Yoshida, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/896,029

(22) Filed: Aug. 29, 2007

(30) Foreign Application Priority Data
Oct. 10, 2006 (KR) 10-2006-0098380

(51) Int. Cl. G11C 11/401; H01L 27/108

(52) U.S. Cl. 365/149; 257/306; 257/E27.088

(57) ABSTRACT

A dynamic random access memory (DRAM) device may include: a semiconductor substrate including an active fin, an active region, and an isolation layer; one or more cell gate structures on a central portion of the active fin; one or more dummy gate structures on a peripheral portion of the active fin; one or more source/drain regions at an upper portion of the active fin adjacent to the one or more cell gate structures; a first insulating interlayer on the semiconductor substrate; a bit line structure electrically connected to the at least one source region; a second insulating interlayer on the first insulating interlayer; one or more capacitors electrically connected to the at least one drain region; a third insulating interlayer on the second insulating interlayer; and a wire connected to the active region and at least one of the one or more dummy gate structures.

### PRIORITY STATEMENT

This application claims priority from Korean Patent Application No. 10-2006-0098380, filed on Oct. 10, 2006, in the Korean Intellectual Property Office (KIPO), the entire contents of which are incorporated herein by reference.

### BACKGROUND

1. Field

Example embodiments relate to dynamic random access memory (DRAM) devices and methods of operating the DRAM devices. Also, example embodiments relate to DRAM devices including fin transistors and methods of operating the DRAM devices including fin transistors.

2. Description of Related Art

Recently, as semiconductor devices have become highly integrated, technologies capable of stably operating DRAM devices have been developed accordingly.

In a DRAM device, a memory cell is selected by address signals when reading and/or writing operations are performed. A voltage higher than a threshold voltage is applied to a word line, which serves as a gate electrode of a transistor included in the selected memory cell, thereby turning on the transistor. However, all transistors included in a plurality of cells of the DRAM device may not have substantially the same voltage, and thus operational failures may frequently occur in the DRAM device. Additionally, when the DRAM device does not operate, a leakage current may be generated so that data stored in the cells may be lost or an excessive standby current may flow.

A distribution of the threshold voltages and the leakage current in an off-state may be decreased by applying a specific voltage to a body of the transistor when the DRAM device is operated. That is, the threshold voltage of the transistor may be increased or decreased by applying a voltage to the body of the transistor.

Generally, a negative bias voltage is applied to the body of the transistor. When the absolute value of the negative bias voltage applied to the body is increased, a variation of the threshold voltage is increased. For example, the threshold voltage of the transistor may be increased accordingly as the absolute value of the negative bias voltage is increased.

A voltage generator, which stably generates and provides the negative bias voltage, is needed in order that the negative bias voltage may be applied to the body of the transistor when the transistor is operated. The number of transistors provided with the negative voltage by the voltage generator may be very large because the negative bias voltage is applied to all of the transistors in the DRAM device. Thus, a large area is needed to form the voltage generator and, therefore, the DRAM device may not easily have a high degree of integration. Additionally, the DRAM device may have operational failures when the voltage generator does not operate properly.

### SUMMARY

Example embodiments may provide DRAM devices having a structure in which a negative bias voltage is not applied to a body of a transistor.

Example embodiments may provide a method of operating a DRAM device having a structure in which a negative bias voltage is not applied to a body of a transistor.

According to example embodiments, a dynamic random access memory (DRAM) device may include: a semiconductor substrate including an active fin, an active region, and an isolation layer; one or more cell gate structures on a central portion of the active fin; one or more dummy gate structures on a peripheral portion of the active fin; one or more source/drain regions at an upper portion of the active fin adjacent to the one or more cell gate structures, the one or more source/drain regions including at least one source region and at least one drain region; a first insulating interlayer on the semiconductor substrate, the first insulating interlayer covering the one or more cell gate structures and the one or more dummy gate structures; a bit line structure electrically connected to the at least one source region; a second insulating interlayer on the first insulating interlayer, the second insulating interlayer covering the bit line structure; one or more capacitors electrically connected to the at least one drain region; a third insulating interlayer on the second insulating interlayer, the third insulating interlayer covering the one or more capacitors; and/or a wire connected to the active region and at least one of the one or more dummy gate structures.

According to example embodiments, a method of operating a dynamic random access memory (DRAM) device having a fin transistor in a unit cell may include: enabling a word line to store data in a capacitor via a bit line, while a body of the fin transistor is grounded; and/or enabling the word line to detect a change in a voltage level of the bit line generated by the data stored in the capacitor, while the body of the fin transistor is grounded.

According to example embodiments, a dynamic random access memory (DRAM) device may include: a semiconductor substrate including an active fin, an active region, and an isolation layer; one or more cell gate structures on a central portion of the active fin; one or more dummy gate structures on a peripheral portion of the active fin; one or more source/drain regions at an upper portion of the active fin adjacent to the one or more cell gate structures, the one or more source/drain regions including at least one source region and at least one drain region; a first insulating interlayer on the semiconductor substrate, the first insulating interlayer covering the one or more cell gate structures and the one or more dummy gate structures; two or more first plugs making contact with the one or more source/drain regions; a second insulating interlayer on the first insulating interlayer, the second insulating interlayer covering the two or more first plugs; a bit line structure electrically connected to the at least one source region via at least a first plug of the two or more first plugs; a third insulating interlayer on the second insulating interlayer, the third insulating interlayer covering the bit line structure; one or more capacitors electrically connected to the at least one drain region via at least a second plug of the two or more first plugs; a fourth insulating interlayer on the third insulating interlayer, the fourth insulating interlayer covering the one or more capacitors; and/or a wire connected to the active region and at least one of the one or more dummy gate structures.

According to example embodiments, a method of operating a dynamic random access memory (DRAM) device having a fin transistor in a unit cell may include: enabling a word line to store data in a capacitor via a bit line, while a bias voltage is not applied to a body of the fin transistor; and/or enabling the word line to detect a change in a voltage level of the bit line generated by the data stored in the capacitor, while the bias voltage is not applied to the body of the fin transistor.

### BRIEF DESCRIPTION OF THE DRAWINGS

The above and/or other aspects and advantages will become more apparent and more readily appreciated from the following detailed description of example embodiments taken in conjunction with the accompanying drawings, in which:

FIG. 1 is a cross-sectional view illustrating a DRAM device according to example embodiments;

FIG. 2 is a perspective view illustrating a fin transistor of the DRAM device in FIG. 1 according to example embodiments;

FIG. 3 is a flow chart explaining a method of operating the DRAM device according to example embodiments;

FIG. 4 is a graph illustrating a relationship between a threshold voltage and a bias voltage applied to transistors bodies, including a planar transistor, a recessed transistor, and a fin transistor, according to example embodiments;

FIG. 5 is a graph illustrating a relationship between a gate-induced drain leakage (“GIDL”) current and a bias voltage applied to transistors bodies, including a recessed transistor and a fin transistor, according to some example embodiments;

FIG. 6 is a graph illustrating a relationship between a junction leakage current and a bias voltage applied to transistors bodies, including a recessed transistor and a fin transistor, according to examples embodiments;

FIG. 7 is a graph illustrating a relationship between an off-current and a bias voltage applied to transistors bodies, including a recessed transistor and a fin transistor, according to example embodiments;

FIG. 8 is a graph illustrating a relationship between a total leakage current in an off-state and a bias voltage applied to transistors bodies, including a recessed transistor and a fin transistor, according to example embodiments; and

FIG. 9 is a graph illustrating a relationship between a data retaining time and a bias voltage applied to the body of a fin transistor according to example embodiments.

### DETAILED DESCRIPTION OF EXAMPLE EMBODIMENTS

Example embodiments will now be described more fully with reference to the accompanying drawings. Embodiments, however, may be embodied in many different forms and should not be construed as being limited to example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein, but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals may refer to like components throughout.

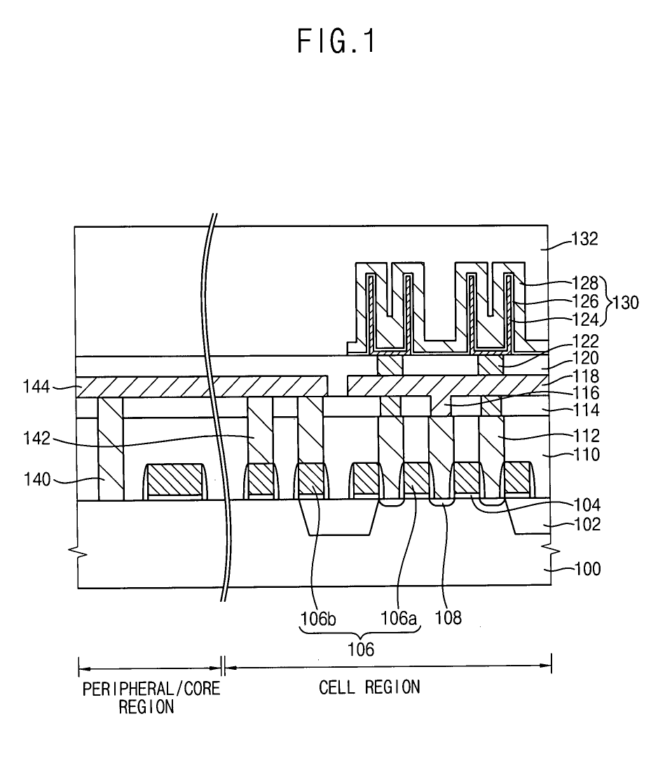

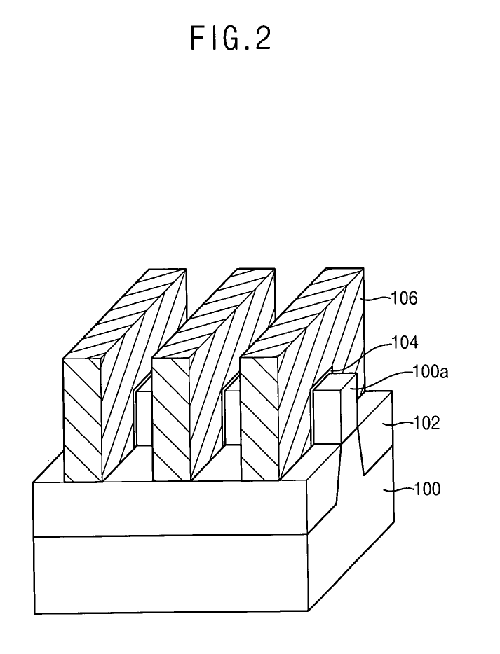

FIG. 1 is a cross-sectional view illustrating a DRAM device according to example embodiments, and FIG. 2 is a perspective view illustrating a fin transistor of the DRAM device in FIG. 1 according to example embodiments.

Referring to FIGS. 1 and 2, a semiconductor substrate 100 may include a peripheral/core region and/or a cell region. Peripheral circuits may be formed in the peripheral/core region and/or a unit cell may be formed in the cell region. An active fin or fins 100a may be formed in the cell region and may have a protrusion shape(s) from the semiconductor substrate 100. An active region may be formed in the peripheral/core region and may have an upper face coplanar with the substrate 100. The semiconductor substrate may include, for example, a semiconductor material such as single crystalline silicon, polysilicon, etc.

An isolation layer 102 may be formed between the active fin or fins 100a. The isolation layer 102 may have a height lower than that of the active fin or fins 100a. In example embodiments, the active fin or fins 100a may have a height of about 80 nm to about 150 nm from an upper face of the isolation layer 102 and/or may have a width below about 100 nm. An upper edge portion of the active fin or fins 100a may be curved so that a punch-through of a channel may be prevented and/or that a gate insulation layer 104 may be uniformly formed on the active fin or fins 100a.

The gate insulation layer 104 may be formed on the active fin or fins 100a. The gate insulation layer 104 may include an oxide which is formed by thermally oxidizing a surface of the active fin or fins 100a.

A plurality of gate electrodes 106 may be formed on the gate insulation layer 104. The gate electrodes 106 may extend in a direction substantially perpendicular to a direction in which the active fin or fins 100a extends. The gate electrodes 106 may include, for example, polysilicon doped with impurities or a metal having a work function higher than that of polysilicon.

Generally, a fin transistor, which may be formed on active-fin-like example embodiments, may have a threshold voltage lower than that of a planar transistor or a recessed transistor. The threshold voltage of the fin transistor may be increased by forming the gate electrodes 106 using a conductive material having a high work function (i.e., energy needed to transport electrons, ions, and/or molecules from the inside of one medium into an adjoining medium).

The gate electrodes 106 may include one or more cell gate electrodes 106a and/or one or more dummy gate electrodes 106b. The one or more cell gate electrodes 106a may serve as a gate electrode of a transistor (or gate electrodes of transistors) included in a unit cell of the DRAM device. The one or more dummy electrodes 106b may be formed so that a loading effect may be decreased when the one or more cell gate electrodes 106a are formed by patterning a conductive layer. Thus, the one or more dummy electrodes 106b may be formed adjacent to a most outer cell gate electrode 106a, but may not be included in the unit cell.

One or more source/drain regions 108 may be formed at an upper portion of the active fin or fins 100a adjacent to the gate electrodes 106. Impurities may be doped into the one or more source/drain regions 108. In example embodiments, N-type impurities such as phosphorus (P), arsenic (As), etc., may be doped into the one or more source/drain regions 108. The one or more source/drain regions 108 may have a lightly doped drain (LDD) structure including, for example, a heavily doped region and/or a lightly doped region.

A first insulating interlayer 110 may be formed on the semiconductor substrate 100 to cover the gate electrodes 106. The first insulating interlayer 110 may include, for example, silicon oxide.

One or more first plugs 112 may be formed through the first insulating interlayer 110 to make contact with the one or more source/drain regions 108. The one or more first plugs 112 may include, for example, polysilicon doped with impurities or a metal. In example embodiments, a plurality of the first plugs 112 may be formed. The first plugs 112 may include one or more source contact plugs and/or one or more drain contact plugs. The one or more source contact plugs may make contact with a source region(s) of the one or more source/drain regions 108 and/or the drain contact plug may make contact with a drain region(s) of the one or more source/drain regions 108.

A second insulating interlayer 114 may be formed on the first insulating interlayer 110 and/or the first plug 112. One or more bit line contact plugs 116 may be formed through the second insulating interlayer 114 to be electrically connected to the one or more source contact plugs. Additionally, a bit line 118 may be formed on the second insulating interlayer 114 to be electrically connected to the one or more bit line contact plugs 116.

A third insulating interlayer 120 may be formed on the second insulating interlayer 114 to cover the bit line 118. One or more storage node contact plugs 122 may be formed through the third insulating interlayer 120 to be electrically connected to the one or more drain contact plugs. The one or more storage node contact plugs 122 may include, for example, polysilicon doped with impurities or a metal.

One or more capacitors 130 may be formed on the third insulating interlayer 120 to be electrically connected to the one or more storage node contact plugs 122. The one or more capacitors 130 may have a cylindrical shape(s). The one or more capacitors 130 may include a lower electrode 124, a dielectric layer 126, and/or an upper electrode 128 that may be sequentially stacked on the third insulating interlayer 120.

A fourth insulating interlayer 132 may be formed on the third insulating interlayer 120 to cover the one or more capacitors 130.

One or more second plugs 140 may be formed through the first insulating interlayer 110 and/or the second insulating interlayer 114 to make contact with the active region. The one or more second plugs 140 may make contact with the active region, and thereby may be electrically connected to a body of the transistor included in the unit cell. Thus, electric signals from the one or more second plugs 140 may be applied to the body of the transistor formed in the cell region.

One or more third plugs 142 may be formed through the first insulating interlayer 110 and the second insulating interlayer 114 to make contact with the one or more dummy gate electrodes 106b.

A conductive wire 144 may be formed on the second insulating interlayer 114 to be electrically connected to the one or more second plugs 140 and/or the one or more third plugs 142. The conductive wire 144 may include, for example, a metal. In example embodiments, the conductive wire 144 may be electrically connected to a terminal that is grounded.

The third insulating interlayer 120 may cover the one or more second plugs 140, the one or more third plugs 142, the conductive wire 144, and/or the second insulating interlayer 114. The fourth insulating interlayer 132 may cover the one or more second plugs 140, the one or more third plugs 142, the conductive wire 144, and/or the third insulating interlayer 120.

Threshold voltage characteristics and/or leakage current characteristics of the fin transistor in the DRAM device may not change much even when a bias voltage applied to the body of the fin transistor may change. Thus, the bias voltage may not need to be applied to the body of the fin transistor. However, a short channel effect may not affect the fin transistor much, so that the fin transistor may have a relatively small threshold voltage distribution in comparison to the planar transistor and/or the recessed transistor. Thus, the DRAM device including the fin transistor may stably operate without applying the bias voltage to the body of the fin transistor.

When the conductive wire 144 may be connected to the terminal that is grounded, the bodies of the one or more cell gate electrodes 106a and/or the one or more dummy gate electrodes 106b may be maintained in the ground level. Thus, a specific voltage may not need to be applied to the body of the fin transistor. Accordingly, a voltage generator that may generate a bias voltage applied to the body may not be required.

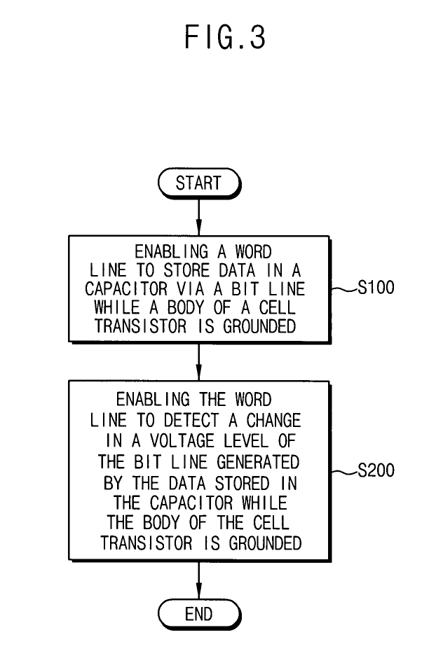

FIG. 3 is a flow chart explaining a method of operating the DRAM device according to example embodiments.

Referring to FIG. 3, at S100, when a writing operation may be performed in the DRAM device, a word line select (WLS) signal may be enabled to apply a first voltage to a gate electrode of the fin transistor included in a selected cell, thereby forming a channel. When the channel may be formed in the selected cell, data may be stored in a capacitor via a bit line. A body of the fin transistor may be in a ground level without a bias voltage being applied thereto.

At S200, when a reading operation may be performed in the DRAM device, the WLS signal may be enabled to apply a first voltage to the gate electrode 106 of the fin transistor included in the selected cell, thereby forming a channel. The data stored in the capacitor 130 may be read by detecting a change in a voltage level of the bit line 118. A bias voltage may not be applied to the body of the fin transistor and/or the body of the fin transistor may be in the ground level.

After the writing and/or reading operations may be performed or when the DRAM device may be in a stand-by state, the WLS signal may be disabled to apply a second voltage to the gate electrode 106 of the fin transistor, thereby turning off the channel. A bias voltage may not be applied to the body of the fin transistor and/or the body of the fin transistor may be in the ground level.

In a related art planar or recessed transistor, a threshold voltage and an off-leakage current may be varied according to a bias voltage applied to a body of a transistor or a bulk substrate. Thus, when reading and/or writing operations are performed in a memory cell, a negative bias voltage is usually applied to the bulk substrate so that a distribution of the threshold voltage and the off-leakage current may be decreased.

However, in the fin transistor, a threshold voltage and an off-leakage current may not vary much according to a bias voltage applied to a body of a transistor and/or a bulk substrate. Thus, a bias voltage may not need to be applied to the body of the transistor when the DRAM device including the fin transistor serving as a cell transistor may be in the stand-by state or when reading and/or writing operations may be performed in the DRAM device. Additionally, the body of the transistor may be in the ground level by connecting the body to a ground, without an additional voltage being applied. As a result, peripheral circuits for applying the bias voltage to the body of the fin transistor may not be formed in the peripheral/core region, thereby increasing an integration degree of the DRAM device.

Hereinafter, characteristics of a conventional planar and/or recessed transistor are compared with those of a fin transistor according to example embodiments.

### Comparison of Threshold Voltage Changes with Respect to Bias Voltage Changes

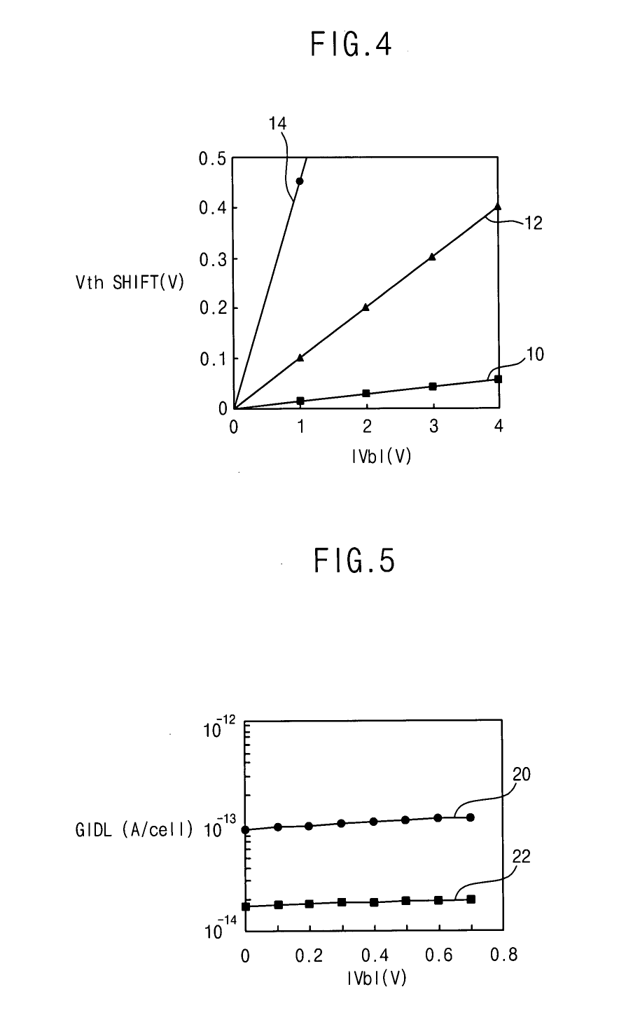

FIG. 4 is a graph illustrating a relationship between a threshold voltage and a bias voltage applied to transistors bodies, including a planar transistor, a recessed transistor, and a fin transistor, according to example embodiments.

In FIG. 4, reference numeral 10 denotes a threshold voltage of the fin transistor when a bias voltage applied to the body of the transistor may vary from about −1 V to about −4 V. Reference numeral 12 represents a threshold voltage of the planar transistor when a bias voltage applied to the body of the transistor may vary from about −1 V to about −4 V. Reference numeral 14 indicates a threshold voltage of the recessed transistor when a bias voltage applied to the body of the transistor may vary from about −1 V to about −4 V.

Referring to FIG. 4, the fin transistor may have a threshold voltage change smaller than those of the planar transistor and/or the recessed transistor. That is, the threshold voltage of the fin transistor may not change very much.

Thus, a bias voltage may not necessarily be applied to the body of the fin transistor in order to decrease a distribution of the threshold voltage.

### Comparison of GIDL Currents with Bias Voltages

FIG. 5 is a graph illustrating a relationship between a GIDL current and a bias voltage applied to transistors bodies, including a recessed transistor and a fin transistor, according to example embodiments.

In FIG. 5, reference numeral 20 denotes a GIDL current of the fin transistor when a bias voltage applied to the body of the fin transistor may vary from about 0 V to about −0.7 V and a drain-gate voltage Vdg between a drain region and a gate may be about 3V. Reference numeral 22 represents a GIDL current in the recessed transistor when a bias voltage applied to the body of the recessed transistor may vary from about 0 V to about −0.7 V and a drain-gate voltage Vdg between a drain region and a gate may be about 3V.

Referring to FIG. 5, the fin transistor may have a GIDL current different from that of the recessed transistor. However, the GIDL currents of the fin transistor and the recessed transistor hardly may change according to the bias voltages applied to the bodies of the fin transistor and the recessed transistor.

### Comparison of Junction Leakage Currents with Bias Voltages

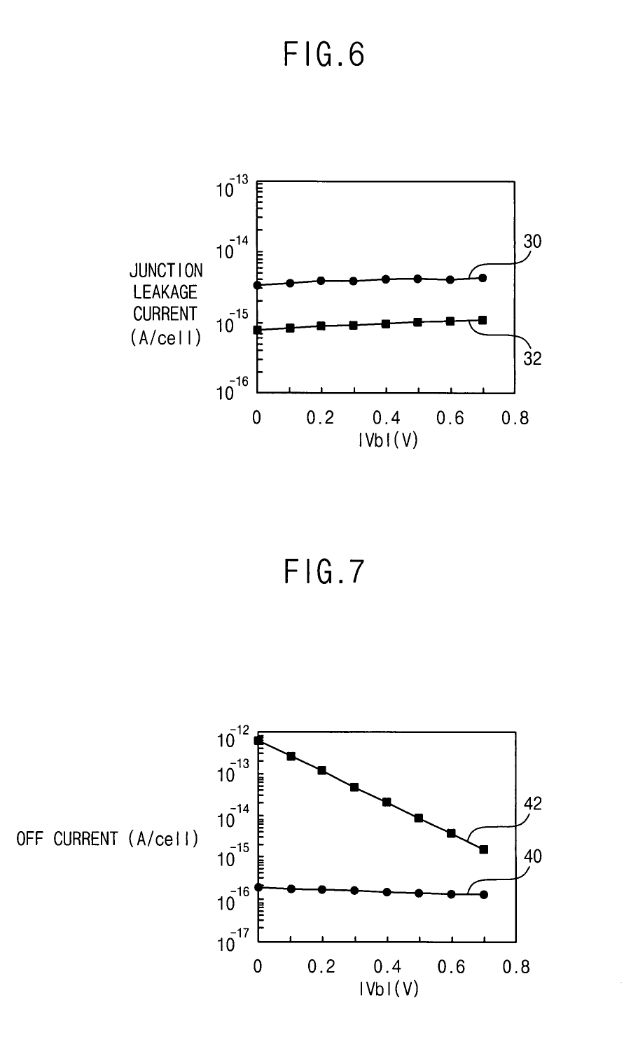

FIG. 6 is a graph illustrating a relationship between a junction leakage current and a bias voltage applied to transistors bodies, including a recessed transistor and a fin transistor, according to example embodiments.

In FIG. 6, reference numeral 30 denotes a junction leakage current in the fin transistor when a bias a voltage applied to the body of the fin transistor may vary from about 0 V to about −0.7 V and a drain voltage Vd may be about 2 V. Reference numeral 32 represents a junction leakage current in the recessed transistor when a bias voltage applied to the body of the recessed transistor may vary from about 0 V to about −0.7 V and a drain voltage Vd may be about 2 V.

Referring to FIG. 6, junction leakage currents of the fin transistor and the recessed transistor hardly may change according to the bias voltages applied to the bodies of the fin transistor and the recessed transistor.

### Comparison of Off-Currents with Bias Voltages

FIG. 7 is a graph illustrating a relationship between an off-current and a bias voltage applied to transistors bodies, including a recessed transistor and a fin transistor, according to example embodiments.

In FIG. 7, reference numeral 40 denotes an off-current between a source region and a drain region of the fin transistor when a bias voltage applied to the body of the fin transistor may vary from about 0 V to about −0.7 V. Reference numeral 42 represents an off-current between a source region and a drain region of the recessed transistor when a bias voltage applied to the body of the recessed transistor may vary from about 0 V to about −0.7 V.

Referring to FIG. 7, an off-current in the fin transistor hardly may change according to the bias voltage applied to the body of the fin transistor. However, an off-current of the recessed transistor may be remarkably reduced as an absolute value of the bias voltage applied to the body of the recessed transistor increases.

### Comparison of Total Leakage Currents in an Off-State with Bias Voltages

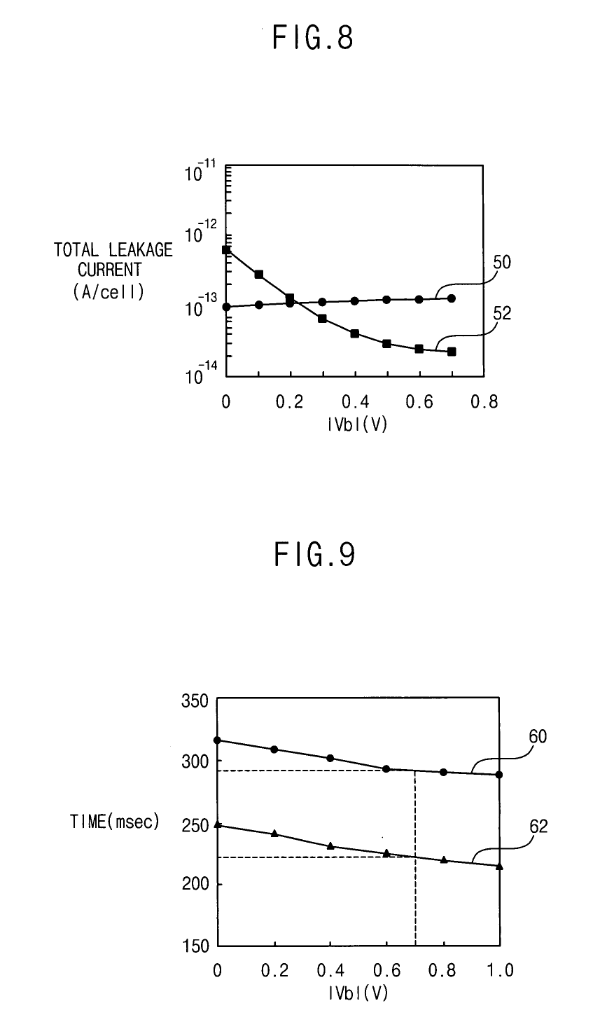

FIG. 8 is a graph illustrating a relationship between a total leakage current in an off-state and a bias voltage applied to transistors bodies, including a recessed transistor and a fin transistor, according to example embodiments. Here, the total leakage current in the off-state means a sum of a GIDL current, a junction leakage current, and an off-current.

In FIG. 8, reference numeral 50 denotes a total leakage current of the fin transistor in an off-state when a bias voltage is applied to the body of the fin transistor. Reference numeral 52 represents a total leakage current of the recessed transistor in an off-state when a bias voltage is applied to the body of the recessed transistor. The total leakage current of the fin transistor in the off-state hardly may change according to the bias voltage applied to the body of the fin transistor. On the other hand, the total leakage current of the recess transistor in the off-state may decrease as an absolute value of the bias voltage applied to the body of the recessed transistor increases.

As discussed above, the total leakage current of the fin transistor in the off-state hardly may change according to the bias voltage applied to the body of the fin transistor. Thus, in a DRAM device including the fin transistor, an additional bias voltage may not necessarily be applied to the body of the fin transistor in order to reduce the total leakage current.

### Estimation of Data Retention Time with Bias Voltages

FIG. 9 is a graph illustrating a relationship between a data retention time and a bias voltage applied to the body of a transistor according to example embodiments.

In FIG. 9, reference numeral 60 denotes a data retention time of a fin transistor when a bias voltage applied to the body of the fin transistor may vary from about 0 V to about −1 V and a voltage of about 0 V may be applied to a gate electrode of the fin transistor. Reference numeral 62 represents a data retention time of the fin transistor when a bias voltage applied to the body of the fin transistor may vary from about 0 V to about −1 V and a voltage of about −0.2 V may be applied to the gate electrode of the fin transistor.

Referring to FIG. 9, in a DRAM device including the fin transistor according to example embodiments, a data retention time increases as a bias voltage applied to the body of the fin transistor may be closer to 0 V. For example, when the bias voltage is about 0 V, the data retention time may increase by 10% from the data retention time when the bias applied is about −0.7 V.

As discussed above, a threshold voltage and a leakage current of the fin transistor when the bias voltage is about 0 V may not be much different from those when the bias voltage is about −0.1 V to about −0.8 V.

Additionally, the data retention time when the bias voltage is about 0 V may be increased in comparison with that when the bias voltage has a negative value.

Thus, a DRAM device including the fin transistor according to example embodiments may stably perform writing and/or reading operations. Particularly, the DRAM device may stably perform writing and/or reading operations by electrically connecting a body of the fin transistor to a ground without applying an additional bias voltage to the body of the fin transistor.

According to example embodiments, a bias voltage may not need to be applied to a body of a transistor, and thus a voltage generator may not be required to operate a DRAM device. Thus, the DRAM device may have a high integration degree. Additionally, simple signals may be used when the DRAM device is operated, thereby decreasing operational failures.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of example embodiments. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific example embodiments disclosed, and that modifications to the disclosed example embodiments, as well as other example embodiments, are intended to be included within the scope of example embodiments.

While example embodiments have been particularly shown and described, it will be understood by those of ordinary skill in the art that various changes in form and details may be made therein without departing from the spirit and scope of the present invention as defined by the following claims.

What is claimed is:

1. A dynamic random access memory (DRAM) device, comprising:
a semiconductor substrate including an active fin, an active region, and an isolation layer;
one or more cell gate structures on a central portion of the active fin;
one or more dummy gate structures on a peripheral portion of the active fin;
one or more source/drain regions at an upper portion of the active fin adjacent to the one or more cell gate structures, the one or more source/drain regions including at least one source region and at least one drain region;
a first insulating interlayer on the semiconductor substrate, the first insulating interlayer covering the one or more cell gate structures and the one or more dummy gate structures;
a bit line structure electrically connected to the at least one source region;
a second insulating interlayer on the first insulating interlayer, the second insulating interlayer covering the bit line structure;
one or more capacitors electrically connected to the at least one drain region;
a third insulating interlayer on the second insulating interlayer, the third insulating interlayer covering the one or more capacitors; and
a wire connected to the active region and at least one of the one or more dummy gate structures.

2. The DRAM device of claim 1, wherein a fin transistor includes the one or more cell gate structures and the one or more source/drain regions, and
wherein the active region is electrically connected to a body of the fin transistor.

3. The DRAM device of claim 1, wherein the wire is electrically connected to a terminal that is grounded.

4. The DRAM device of claim 1, wherein the wire comprises:
one or more first plugs formed through the first insulating interlayer, the one or more first plugs making contact with the active region;
one or more second plugs formed through the first insulating interlayer, the one or more second plugs making contact with the at least one of the one or more dummy gate structures; and
a conductive wire on the first insulating interlayer, the conductive wire being electrically connected to the one or more first plugs and the one or more second plugs.

5. A method of operating a dynamic random access memory (DRAM) device having a fin transistor in a unit cell, the method comprising:
enabling a word line to store data in a capacitor via a bit line, while a body of the fin transistor is grounded; and
enabling the word line to detect a change in a voltage level of the bit line generated by the data stored in the capacitor, while the body of the fin transistor is grounded.

6. The method of claim 5, wherein the body of the fin transistor is electrically connected to a terminal that is grounded.

7. The DRAM device of claim 1, wherein the active region includes an upper face coplanar with the isolation layer.

8. The DRAM device of claim 1, wherein the one or more capacitors include:
a lower electrode;
a dielectric layer; and
an upper electrode.

9. The DRAM device of claim 8, wherein the lower electrode, dielectric layer, and upper electrode are sequentially stacked on the second insulating interlayer.

10. The Dram device of claim 1, further comprising two or more first plugs making contact with the one or more source/drain regions, and the bit line structure is electrically connected to the at least one source region via at least one of the two or more first plugs and one or more capacitors are electrically connected to the at least one drain region via at least one of the two or more first plugs.

11. The DRAM device of claim 10, wherein a fin transistor includes the one or more cell gate structures and the one or more source/drain regions, and
wherein the active region is electrically connected to a body of the fin transistor.

12. The DRAM device of claim 10, wherein the wire is electrically connected to a terminal that is grounded.

13. The DRAM device of claim 10, wherein the wire comprises:
one or more second plugs formed through the first and second insulating interlayers, the one or more second plugs making contact with the active region;
one or more third plugs formed through the first and second insulating interlayers, the one or more third plugs making contact with the at least one of the one or more dummy gate structures; and
a conductive wire on the second insulating interlayer, the conductive wire being electrically connected to the one or more second plugs and the one or more third plugs.

14. The DRAM device of claim 10, wherein the active region includes an upper face coplanar with the isolation layer.

15. The DRAM device of claim 10, wherein the one or more capacitors include:
a lower electrode;
a dielectric layer; and
an upper electrode.

16. The DRAM device of claim 15, wherein the lower electrode, dielectric layer, and upper electrode are sequentially stacked on the third insulating interlayer.

17. A method of operating a dynamic random access memory (DRAM) device having a fin transistor in a unit cell, the method comprising:
enabling a word line to store data in a capacitor via a bit line, while a bias voltage is not applied to a body of the fin transistor; and
enabling the word line to detect a change in a voltage level of the bit line generated by the data stored in the capacitor, while the bias voltage is not applied to the body of the fin transistor.
